(19) United States
(12) Patent Application Publication
(10) Pub. No.: US 2013/0082327 A1
(43) Pub. Date: Apr. 4, 2013

(54) SEMICONDUCTOR DEVICE

(71) Applicants: Cheol Ho CHO, Bucheon-si (KR); Choul Joo Ko, Seongnam-si (KR)

(72) Inventors: Cheol Ho CHO, Bucheon-si (KR); Choul Joo Ko, Seongnam-si (KR)

(21) Appl. No.: 13/252,284

(22) Filed: Oct. 4, 2011

(51) Int. Cl. H01L 29/78

(52) U.S. Cl. 257/336; 257/E29.266

(57) ABSTRACT

A semiconductor device including a first conductive epitaxial layer, a second conductive type first well provided in the first conductive epitaxial layer, a first conductive body provided in the first conductive epitaxial layer, a second conductive type drain extension region provided in the first conductive epitaxial layer and interposed between the first conductive body and the second conductive type first well, a second conductive type second well provided in the second conductive type first well, and a gate provided in the first conductive epitaxial layer.

### BACKGROUND

Power semiconductor devices preferably operate at high voltages compatible to theoretical breakdown voltages thereof. As a result, when exterior systems using high voltages are controlled by integrated circuits, the components of the integrated circuits require a semiconductor device to control high voltage. These semiconductor devices for high-voltages require a structure having a high breakdown voltage. Meaning, in a drain or source of a transistor to which a high voltage is directly applied, a punch through voltage between the drain/source and a semiconductor substrate, and breakdown voltage between the drain/source and a well or the substrate should be higher than the applied high voltage.

Lateral diffused MOS (LDMOS) is a representative MOS for high-voltage semiconductor devices. In the LDMOS, the drain is disposed laterally to allow current to flow laterally and a drift region is disposed between the channel and the drain to secure high breakdown voltage. A great deal of research is conducted to increase breakdown voltage and reduce on-resistance (such as specific on-resistance) between the source and the drain in semiconductor devices for high voltage such as LDMOSs.

Embodiments relate to a semiconductor device. More specifically, the embodiments relate to an LDMOS (lateral double diffused MOS) to reduce on-resistance and increase in breakdown voltage.

Embodiments relate to a semiconductor device that substantially obviates one or more problems due to limitations and disadvantages of the related art.

In accordance with embodiments, there is provided a semiconductor device and a method for manufacturing the same to reduce on-resistance and increase breakdown voltage.

In accordance with embodiments, a semiconductor device includes at least one of the following: a first conductive type epitaxial layer, a second conductive type first well provided in the first conductive type epitaxial layer, a first conductive type body provided in the first conductive type epitaxial layer, a second conductive type drain extension region provided in the first conductive type epitaxial layer, the second conductive type drain extension region being interposed between the first conductive type body and the second conductive type first well, a second conductive type second well provided in the second conductive type first well, and a gate provided on and/or over the first conductive type epitaxial layer.

The second conductive type drain extension region may contact the first conductive type body and the second conductive type first well.

The semiconductor device may further include a first conductive type drain extension region provided in the first conductive type epitaxial layer under the second conductive type drain extension region.

The semiconductor device may further include a second conductive type buried layer provided in the first conductive type epitaxial layer under the second conductive type first well and the second conductive type drain extension region.

The semiconductor device may further include a field oxide film provided on and/or over the first conductive type epitaxial layer and exposing a portion of the second conductive type drain extension region and a portion of the second conductive type first well.

The gate may be provided in the exposed portion of the second conductive type drain extension region and on and/or over the field oxide film adjacent the portion of the exposed portion of the second conductive type drain extension region.

The semiconductor device may further include a source provided in the first conductive type body, and a drain provided in the second conductive type second well.

The bottom surface of the second conductive type drain extension region may contact the uppermost surface of the first conductive type drain extension region.

The first conductive type drain extension region may contact one side of the second conductive type first well.

The second conductive type second well may be spaced from the second conductive type buried layer and the second conductive type drain extension region.

The second conductive type first well may surround the second conductive type second well and may contact the second conductive type buried layer.

The semiconductor device may further include a first conductive type drain extension region provided between the second conductive type buried layer and the second conductive type drain extension region.

The bottom surface of the first conductive type drain extension region may contact the uppermost surface of the second conductive type buried layer.

The semiconductor device may further include a first conductive type drain extension region provided in the first conductive type epitaxial layer under the second conductive type drain extension region and the first conductive type body.

The uppermost surface of the first conductive type drain extension region may contact the bottom surface of the second conductive type drain extension region and the bottom surface of the first conductive type body.

The concentration of the second conductive type impurity of the second conductive type drain extension region may be higher than the concentration of the second conductive type impurity of the second conductive type first well.

The concentration of the second conductive type impurity of the second conductive type second well may be higher than the concentration of the second conductive type impurity of the second conductive type first well and may be lower than the concentration of the second conductive type impurity of the drain.

The concentration of the impurity of the first conductive type drain extension region may be higher than the concentration of the impurity of the first conductive type epitaxial layer and may be lower than the concentration of the impurity of the first conductive type body.

The semiconductor device may be further comprise a first conductive type impurity region provided in the first conductive type body, the first conductive type impurity region contacting the source.

The first conductive type may be a p-type and the second conductive type is an n-type.

### DRAWINGS

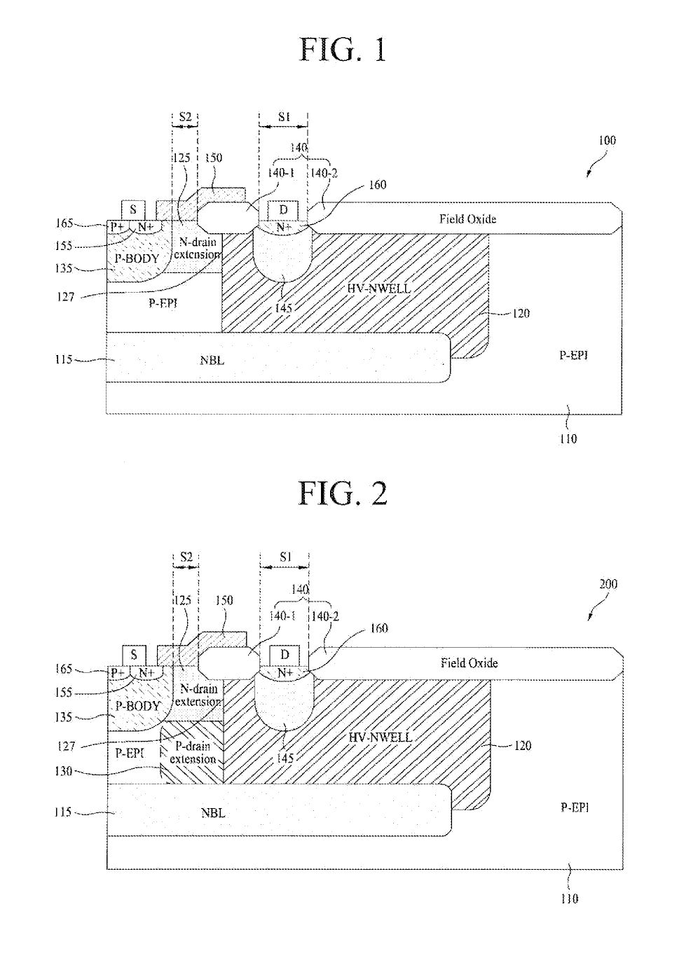

Example FIG. 1 illustrates a sectional view of an LDMOS in accordance with embodiments.

Example FIG. 2 illustrates a sectional view of an LDMOS in accordance with embodiments.

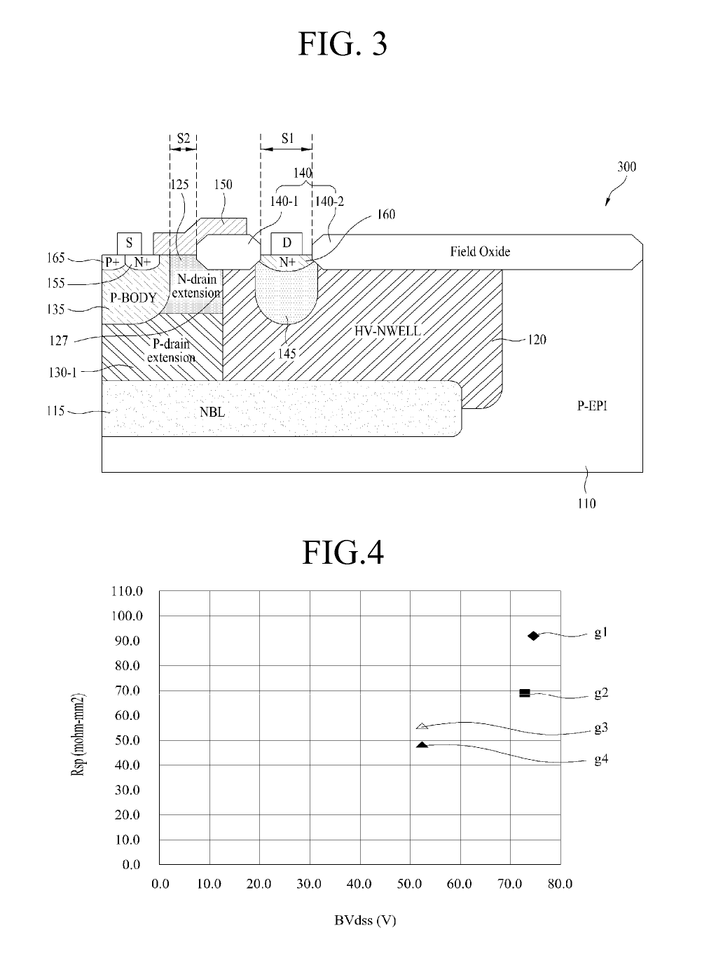

Example FIG. 3 illustrates a sectional view illustrating an LDMOS in accordance with embodiments.

Example FIG. 4 illustrates properties between breakdown voltage and on-resistance of the LDMOS illustrated in example FIG. 1.

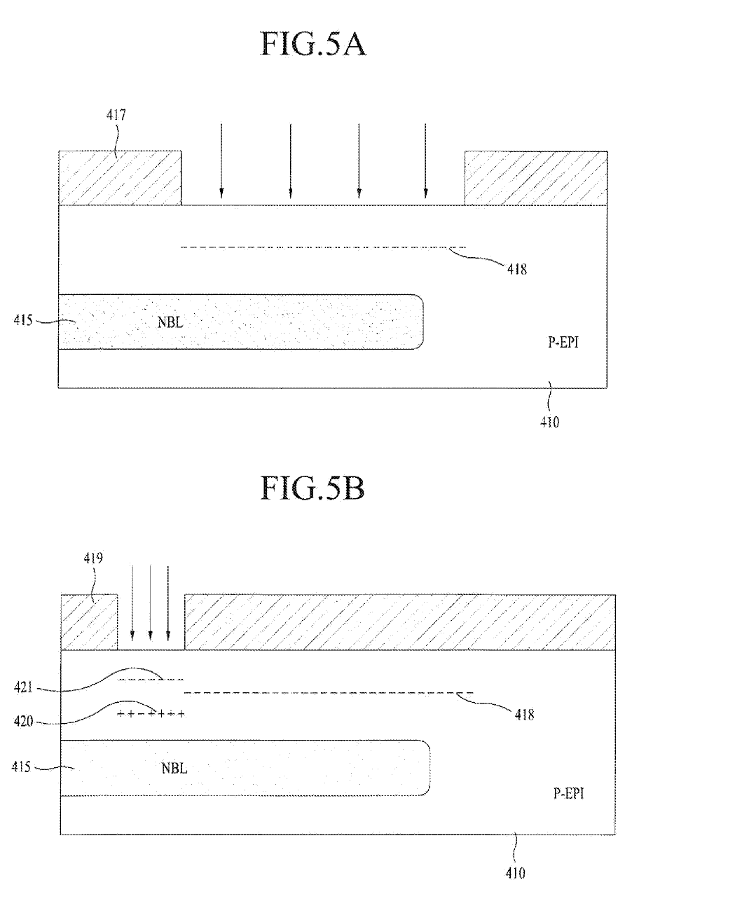

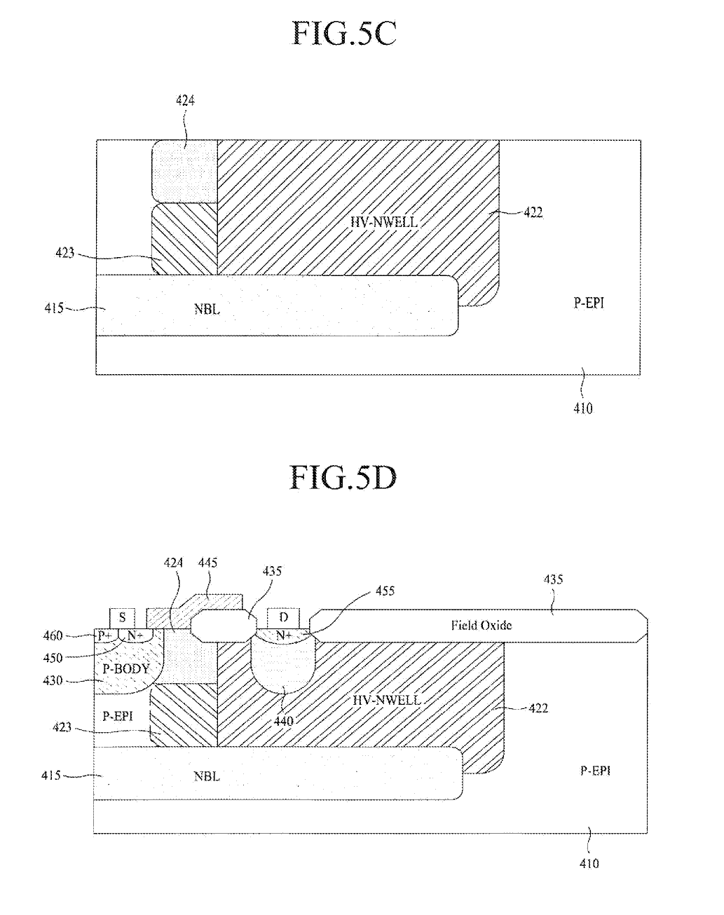

Example FIGS. 5A to 5D illustrates sectional views of a process for manufacturing the LDMOS in accordance with embodiments.

### DESCRIPTION

Other aspects, features and advantages of embodiments of the invention will be more clearly understood from the following detailed description taken in conjunction with the accompanying drawings.

As illustrated in example FIG. 1, an LDMOS 100 in accordance with embodiments includes a first conductive type epitaxial layer 110, a second conductive type buried layer or n-buried layer (NBL) 115, a second conductive type first well or high voltage (HV) n-well 120, a second conductive type drain extension region or n-drain; 125, a first conductive body or p-body 135, a field oxide film 140, a second conductive type second well 145, a gate 150, a second conductive type source 155 and a second conductive type drain 160, and a first conductive impurity region 165. The first conductive type is a p-type and the second conductive type is an n-type, although the conductive type is not limited thereto.

The first conductive epitaxial layer 110 is grown on and/or over a semiconductor substrate. For example, the first conductive epitaxial layer 110 may be a p-type epitaxial layer, although not limited thereto.

The second conductive type buried layer 115 is provided in the first conductive epitaxial layer 110. For example, the second conductive type buried layer 115 is spaced from the uppermost surface of the first conductive epitaxial layer 110 by a predetermined distance and may be provided in one region of the first conductive epitaxial layer 110. The second conductive type buried layer 115 may be an n-type buried layer, although not limited thereto.

The second conductive type first well 120 is provided in the first conductive epitaxial layer 110 and disposed on and/or over the second conductive type buried layer 115. For example, the second conductive type first well 120 may be disposed between the uppermost surface of the first conductive epitaxial layer 110 and the second conductive type buried layer 115. One region of the bottom surface of the second conductive type first well 120 may contact one region of the uppermost surface of the second conductive type buried layer 115. In addition, the other region of the bottom surface of the second conductive type first well 120 may contact a portion of the side of the second conductive type buried layer 115. The second conductive type first well 120 may be an n-type well, although not limited thereto.

The second conductive type drain extension region 125 is spaced from the second conductive type buried layer 115 and is provided in the first conductive epitaxial layer 110 disposed on and/or over the second conductive type buried layer 115. For example, the second conductive type drain extension region 125 may be interposed between the second conductive type buried layer 115 and the uppermost surface of the first conductive epitaxial layer 110 and may be provided from the surface of the first conductive epitaxial layer 110 to a predetermined region inside the first conductive epitaxial layer 110. In addition, one side of the second conductive type drain extension region 125 may contact a portion of one side of the second conductive type first well 120.

The first conductive body 135 is provided in the first conductive epitaxial layer 110 and disposed on and/or over the second conductive type buried layer 115. For example, the first conductive body 135 may be provided from the surface of the LDMOS 100 to a predetermined region inside the first conductive epitaxial layer 110, and may be spaced from the second conductive type buried layer 115. One side of the first conductive body 135 contacts the other side of the second conductive type drain extension region 125. Meaning, the second conductive type drain extension region 125 may be interposed between the first conductive body 135 and the second conductive type first well 120 and may contact the first conductive body 135 and the second conductive type first well 120.

The field oxide film 140 is provided on and/or over the first conductive epitaxial layer 110. The field oxide film 140 may be provided on and/or over the second conductive type drain extension region 125 and the second conductive type first well 120. The field oxide film 140 may expose a partial region S1 of the second conductive type first well 120 and a partial region S2 of the second conductive type drain extension region 125.

The field oxide film 140 may include a first field oxide film 140-1 and a second field oxide film 140-2. The first field oxide film 140-1 may be spaced from the first conductive body 135 and may be provided on and/or over a portion of the second conductive type drain extension region 125 which contacts an interface 127 and a portion of the second conductive type first well 120. The interface 127 may be an area at which the second conductive type drain extension region 125 contacts the second conductive type first well 120. For example, the first field oxide film 140-1 may extend from the second conductive type drain extension region 125 to the second conductive type first well 120. The second field oxide film 140-2 is spaced from the first field oxide film 140-1 and may be provided in other regions of the second conductive type first well 120 and on and/or over the first conductive epitaxial layer 110.

The second conductive type second well 145 is provided in the second conductive type first well 120, and spaced from the second conductive type buried layer 120 and the second conductive type drain extension region 125 and exposed by the field oxide film 140. For example, the second conductive type second well 145 may be provided in the partial region S1 of the second conductive type first well 120 exposed by the field oxide film 140. Meaning, the second conductive type first well 120 may surround the second conductive type second well 145 in regions other than the surface of the second conductive type second well 145 exposed by the field oxide film 140.

The gate 150 is provided on and/or over partial regions of the field oxide film 140, the second conductive type drain extension region 125 adjacent to the field oxide film 140, and the first conductive body 135. For example, the gate 150 is provided on and/or over the first field oxide film 140-1 and may extend to the partial region S2 of the second conductive type drain extension region 125 adjacent to the first field oxide film 140-1, and one region of the source 155 provided in the first conductive body 135.

The source 155 is provided in one region of the first conductive body 135 and may be formed by doping a second conductive type impurity (N+). For example, the source 155 may be spaced from the second conductive type drain extension region 125. A portion of the source 155 is disposed under the gate 150 and vertically overlaps the gate 150. The vertical direction may be perpendicular to the surface of the first conductive epitaxial layer 110.

The drain 160 may be provided in the second conductive type second well 145 and may be formed by doping the second conductive type impurity (N+). For example, the drain 160 is provided on and/or over the surface of the second conductive type second well 145 exposed by the field oxide film 140 and is exposed by the field oxide film 140.

The first conductive impurity region 165 may be provided in the other region of the first conductive body 135 such that the first conductive impurity region 165 contacts the source 155.

The concentration of the second conductive type impurity increases in the order of the second conductive type first well 120, the second conductive type drain extension region 125, the second conductive type second well 145, the second conductive type source 155 and the drain 160. For example, the concentration of the second conductive type impurity in the second conductive type drain extension region 125 may be higher than the second conductive type impurity of the second conductive type first well 120. The concentration of the second conductive type impurity in the second conductive type second well 145 may be higher than the concentration of the second conductive type impurity in the second conductive type first well 120 and the second conductive type drain extension region 125 may be lower than the concentration of the second conductive type impurity in the drain 160.

The drain 160, the second conductive type second well 145, the second conductive type first well 120, and the second conductive type drain extension region 125 form a lateral drain region of the LDMOS 100. In accordance with embodiments, the concentration of impurities in the lateral region of the LDMOS 100 may have a broad distribution due to the second conductive type second well 145 provided in the second conductive type first well 120. In addition, a safe operating area of LDMOS may be increased due to the broad impurity concentration distribution of the lateral drain region of the LDMOS 100.

In addition, in accordance with embodiments, on-resistance, for example, specific on-resistance Rₛₚ, may be decreased by the second conductive type drain extension region 125. On-resistance may be decreased by increasing the concentration of the second conductive type drain extension region 125.

In addition, in accordance with embodiments, breakdown voltage may be increased, when a reverse bias is applied to the LDMOS 100. This is the reason that the electric field concentration is decreased in the first conductive epitaxial layer 110 interposed between the first conductive body 135 and the second conductive type buried layer 115 due to the second conductive type drain extension region 125, and that the second conductive type first well 120 surrounds the second conductive type second well 145 to secure sufficient extension of the depletion region.

FIG. 2 is a sectional view illustrating an LDMOS in accordance with embodiments. The same reference numerals as in FIG. 1 indicate identical elements and the description of the identical elements is brief or omitted.

As illustrated in example FIG. 2, in addition to elements of embodiments illustrated in example FIG. 1, the LDMOS 200 further includes a first conductive drain extension region or p-drain extension region 130. The first conductive drain extension region 130 is provided in the first conductive epitaxial layer 110 between the second conductive type drain extension region 125 and the first conductive buried layer 115. For example, the first conductive drain extension region 130 and the second conductive type drain extension region 125 may be sequentially interposed between the second conductive type buried layer 115 and the surface of the first conductive epitaxial layer 110 and may be laminated in this order.

The uppermost surface of the first conductive drain extension region 130 contacts the bottom surface of the second conductive type drain extension region 125, and the bottom surface of the first conductive drain extension region 130 contacts the uppermost surface of the second conductive type buried layer 120. One side of the first conductive drain extension region 130 may contact another portion of one side of the second conductive type first well 120. The bottom surface of the first conductive body 135 may contact a portion of the first conductive drain extension region 130.

The concentration of the first conductive impurity may increase in the order of the first conductive epitaxial layer 110, the first conductive drain extension region 130, and the first conductive body 135. For example, the concentration of the impurity of the first conductive drain extension region 130 is higher than the concentration of the impurity of the first conductive epitaxial layer 110 and is lower than the concentration of the impurity of the first conductive body 135.

The drain 160, the second conductive type second well 145, the second conductive type first well 120, the second conductive type drain extension region 125, and the first conductive drain extension region 130 illustrated in example FIG. 2 may form a lateral drain region of the LDMOS 100.

The LDMOS 200 decreases on-resistance, for example, specific on-resistance Rₛₚ, and increases breakdown voltage through the second conductive type drain extension region 125. In addition, as compared to embodiments illustrated in example FIG. 1, the LDMOS 200 illustrated in example FIG. 2 can further increase breakdown voltage. This is the reason that in the LDMOS 200, the density of the electric field between the first conductive body 135 and the second conductive type buried layer 120 is decreased and the depletion region is further extended through the first conductive drain extension region 130.

Example FIG. 3 illustrates an LDMOS 300 according to another embodiment of the present invention. The same reference numerals as in FIG. 2 indicate identical elements and description of the identical elements is brief or omitted.

Referring to FIG. 3, in addition to elements of the embodiment shown in FIG. 1, the LDMOS 300 further includes a first conductive drain extension region 130-1. The formation range of the first conductive drain extension region 130-1 of the LDMOS 300 is different from that of the first conductive drain extension region 130.

The first conductive drain extension region 130-1 is disposed between the second conductive type buried layer 115 and the second conductive type drain extension region 125, and between the second conductive type buried layer 115 and the first conductive body 135.

The uppermost surface of the first conductive drain extension region 130-1 may contact the bottom surface of the second conductive type drain extension region 125 and the bottom surface of the first conductive body 135. That is, the first conductive drain extension region 130-1 may extend to the first conductive epitaxial layer 110 under the first conductive body 135. In addition, the bottom surface of the first conductive drain extension region 130-1 may contact the uppermost surface of the second conductive type buried layer 115.

As compared to embodiments illustrated in example FIG. 2, the LDMOS 300 can further increase breakdown voltage. This is the reason that the first conductive drain extension region 130-1 extends to the first conductive epitaxial layer 110 under the first conductive body 135.

Example FIG. 4 illustrates properties between breakdown voltage (BV_{dss}) and on-resistance (Rₛₚ) of the LDMOS 100 illustrated in example FIG. 1. g1, g3 and g4 represent breakdown voltages and on-resistances of a general LDMOS, and g2 represents breakdown voltage and on-resistance of the LDMOS 200 illustrated in example FIG. 2. Generally, as breakdown voltage increases, on-resistance increases. g3 and g4 exhibit on-resistance of 50 to 60 mohm-min² at a breakdown voltage of 50V. g1 exhibits on-resistance of 90 mohm-mm² at a breakdown voltage of 70V, while g2 represents on-resistance of 70 mohm-mm² at a breakdown voltage of 70V. In accordance with embodiments, although the breakdown voltage is increased to about 75V, on-resistance of about 70 mohm-mm² can be obtained. Accordingly, embodiments enable a decrease of on-resistance and an increase in breakdown voltage.

Example FIGS. 5A to 5D illustrate a process for manufacturing the LDMOS in accordance with embodiments.

As illustrated in example FIG. 5A, a first conductive, for example, p-type, epitaxial layer 410 is grown on and/or over a substrate. A second conductive type buried layer 415 is formed in the first conductive epitaxial layer 410. For example, the second conductive type buried layer 415 is formed by injecting a second conductive type, for example, n-type, impurity into the first conductive epitaxial layer 410. In addition, the first conductive epitaxial layer 410 is subjected to a photolithography process to form a first photoresist pattern 417 to expose one region of the first conductive epitaxial layer 410. The second conductive type first impurity 418 is injected into the epitaxial layer 410 using the first photoresist pattern 417 as a mask. The second conductive type first impurity 418 may be injected into the first conductive epitaxial layer 410 disposed on one region of the second conductive type buried layer 415.

As illustrated in example FIG. 5B, the first photoresist pattern 417 is then removed through an ashing or stripping process to form a second photoresist pattern 419 to expose the other region of the first conductive epitaxial layer 410. At this time, the region of the first conductive epitaxial layer 410 exposed by the second photoresist pattern 419 does not overlap the region of epitaxial layer 410 exposed by the first photoresist pattern 417.

The first conductive second impurity 420 is injected into the first conductive epitaxial layer 410 using the second photoresist pattern 419 as a mask. At this time, the first conductive second impurity 420 may be boron and may be injected into the first conductive epitaxial. layer 410 on and/or over the other region of the second conductive type buried layer 415. For example, the injected first impurity 418 and second impurity 420 are spaced from each other and injected into the first conductive epitaxial layer 410 disposed on and/or over the second conductive type buried layer 415.

Then, the second conductive type third impurity 421 is injected into the first conductive epitaxial layer 410 using the second photoresist pattern 419 as a mask on and/or over the region where the second impurity 420 is injected. For example, the third impurity 421 may be an n-type impurity, for example, phosphorus, antimony or arsenic. By injecting the third impurity 421 to a smaller thickness than the second impurity 420, the third impurity 421 may be injected into the first conductive epitaxial layer 410 such that it is spaced from the second impurity 420 and the first impurity 418. Unlike those mentioned above, the third impurity 421 may be first injected and the second impurity 420 may then be injected to a larger depth than the third impurity 421.

As illustrated in example FIG. 5C, the second photoresist pattern 419 is then removed through an ashing or stripping process. Then, the second photoresist pattern 419 is subjected to an annealing process to diffuse the first to third impurities 418, 420 and 421 in the first conductive epitaxial layer 410 and thereby form a second conductive type first well 422, a first conductive drain extension region 423 and a second conductive type drain extension region 424 which are adjacent to one another.

The second conductive type first well 422 may be diffused from the surface of the first conductive epitaxial layer 410 to one region of the second conductive type buried layer 415. In addition, the first conductive drain extension region 423 is formed on the other region of the second conductive type buried layer 410, and the second conductive type drain extension region 424 is formed on and/or over the first conductive drain extension region 423. For example, the second conductive type first well 422 may be diffused such that a partial region of the uppermost surface of the second conductive type buried layer 415 contacts a partial region of the bottom surface of the second conductive type first well 422. In addition, the first conductive drain extension region 423 may extend such that the bottom surface of the first conductive drain extension region 423 contacts the other region of the uppermost surface of the second conductive type buried layer 415 and one side of the first conductive drain extension region 423 contacts one portion of one side of the second conductive type first well 422.

In addition, the second conductive type drain extension region 424 may extend such that the bottom surface of the second conductive type drain extension region 424 contacts the uppermost surface of the first conductive drain extension region 423 and the second conductive type drain extension region 424 may extend such that one side of the second conductive type drain extension region 424 contacts the other portion of one side of the second conductive type first well 422.

As illustrated in example FIG. 5D, a first conductive impurity is then injected into the first conductive epitaxial layer 410 provided with the first conductive drain extension region 423 and the second conductive type drain extension region 424 to form a first conductive body, for example, a p-body 430. Formation of the first conductive body 430 in the first conductive epitaxial layer 410 may be carried out by selectively doping boron (B) ions at a predetermined dose into the first conductive epitaxial layer 410. The first conductive body 430 may contact the other side of the second conductive type drain extension region 424. In addition, the bottom surface of the first conductive body 430 may contact the edge of the first conductive drain extension region 423.

A field oxide film 435 is then formed on and/or over the surface of the first conductive epitaxial layer 410. For example, the field oxide film 435 made of field oxide may be formed using a common local oxidation of silicon (LOCOS) method. The field oxide film 435 is spaced from the first conductive body 430 and is formed on and/or over the surface of the first conductive epitaxial layer 410 adjacent to the interface between the second conductive type drain extension region 424 and the second conductive type first well 422 such that it extends to the second conductive type drain extension region 424 and the second conductive type first well 422. In addition, the field oxide film 435 may expose a partial region of the second conductive type first well 422 and a portion of the second conductive type drain extension region 424.

A second conductive type second well 440 is then formed in the second conductive type first well 422 such that it is spaced from the second conductive type buried layer 415 and the second conductive type drain extension region 424. The second conductive type second well 440 can be formed on and/or over the surface of the partial region of the exposed second conductive type first well 422 by selectively injecting the second conductive type impurity into the partial region of the second conductive type first well 422 exposed by the field oxide film 435.

A gate 445 is then formed such that it extends on one side region of the field oxide film 435 formed on and/or over the surface of the first conductive epitaxial layer 410 adjacent to the interface between the second conductive type drain extension region 424 and the second conductive type first well 422, the second conductive type drain extension region 424 adjacent to the one side region, and the first conductive body 430.

A second conductive type impurity is then injected into the first conductive body 430 and the second conductive type second well 440 to form a source 450 and a drain 455. In addition, a first conductive impurity is injected into the first conductive body 430 to form a body contact 460. The source 450 is formed in one region of the first conductive body 430 and the drain 455 is formed in the second conductive type second well 440. In addition, the first conductive impurity is injected into the other region of the first conductive body 430 to form a first conductive impurity region 460 which contacts the source 450.

As apparent from fore-going, the semiconductor device and the method for manufacturing the same according to the embodiments can reduce on-resistance of an LDMOS and increase breakdown voltage thereof by further performing a process of forming a mask to form the first conductive drain extension region 423 and the second conductive type drain extension region 424, and forming the second conductive type second well 440 in the second conductive type first well 422.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
an epitaxial layer having a first conductive type;
a first well having a second conductive type provided in the epitaxial layer;
a body having a first conductive type provided in the epitaxial layer;
a first drain extension region having a second conductive type provided in the first epitaxial layer, wherein the first drain extension region is interposed between the body and the first well;
a second well having a second conductive type provided in the first well; and
a gate provided over the epitaxial layer.

2. The semiconductor device of claim 1, wherein the drain extension region contacts the body and the first well.

3. The semiconductor device of claim 1, further comprising:
a field oxide film provided over the epitaxial layer and exposing a portion of the first drain extension region and a portion of the first well.

4. The semiconductor device of claim 3, wherein the gate is provided in the exposed portion of the first drain extension region and over the field oxide film adjacent to the exposed portion of the first drain extension region.

5. The semiconductor device of claim 1, further comprising:
a source provided in the body; and
a drain provided in the second well.

6. The semiconductor device of claim 5, wherein:
the concentration of the second conductive type impurity of the second well is higher than the concentration of the second conductive type impurity of the first well; and
the concentration of the second conductive type impurity of the second well is lower than the concentration of the second conductive type impurity of the drain.

7. The semiconductor device of claim 5, further comprising:
an impurity region having a first conductive type provided in the body and which contacts the source.

8. The semiconductor device of claim 1, wherein the concentration of the second conductive type impurity of the first drain extension region is higher than the concentration of the second conductive type impurity of the first well.

9. The semiconductor device of claim 1, wherein:
the first conductive type is a p-type; and
the second conductive type is an n-type.

10. The semiconductor device of claim 1, further comprising:
a second drain extension region having a first conductive type provided in the epitaxial layer under the first drain extension region and the body.

11. A semiconductor device comprising:
an epitaxial layer having a first conductive type;
a first well having a second conductive type provided in the epitaxial layer;
a body having a first conductive type provided in the epitaxial layer;
a first drain extension region having a second conductive type provided in the first epitaxial layer, wherein the first drain extension region is interposed between the body and the first well;
a buried layer having a second conductive type provided in the epitaxial layer under the first well and the first drain extension region
a second well having a second conductive type provided in the first well; and
a gate provided over the epitaxial layer.

12. The semiconductor device of claim 11, wherein the second well is spaced from the buried layer and the first drain extension region.

13. The semiconductor device of claim 11, wherein the first well surrounds the second well and contacts the buried layer.

14. The semiconductor device of claim 11, further comprising:
a second drain extension region provided between the buried layer and the first drain extension region.

15. The semiconductor device of claim 14, wherein the bottom surface of the second drain extension region contacts the uppermost surface of the buried layer.

16. The semiconductor device of claim 15, wherein the uppermost surface of the second drain extension region contacts the bottom surface of the first drain extension region and the bottom surface of the body.

17. A semiconductor device comprising:
an epitaxial layer having a first conductive type;
a first well having a second conductive type provided in the epitaxial layer;
a body having a first conductive type provided in the epitaxial layer;
a first drain extension region having a second conductive type provided in the first epitaxial layer, wherein the first drain extension region is interposed between the body and the first well;
a second drain extension region having a first conductive type provided in the epitaxial layer under the first drain extension region;
a second well having a second conductive type provided in the first well; and
a gate provided over the epitaxial layer.

18. The semiconductor device of claim 17, wherein the bottom surface of the first drain extension region contacts the uppermost surface of the second drain extension region.

19. The semiconductor device of claim 17, wherein the second drain extension region contacts one side of the first well.

20. The semiconductor device of claim 17, wherein:
the concentration of the impurity of the second drain extension region is higher than the concentration of the impurity of the epitaxial layer; and
the concentration of the impurity of the second drain extension region is lower than the concentration of the impurity of the body.
